(19) United States
(12) Patent Application Publication
(10) Pub. No.: US 2026/0304677 A1
(43) Pub. Date: Oct. 1, 2026

(54) POWER SUPPLY UNIT ADAPTER SET

(71) Applicant: HEWLETT PACKARD ENTERPRISE DEVELOPMENT LP, Spring, TX (US)

(72) Inventors: Yu Han Lin, Taoyuan City (TW); Kuei Ching Hsu, Taipei (TW); Hsueh-Yu Chao, Taipei (TW)

(21) Appl. No.: 19/090,529

(22) Filed: Mar. 26, 2025

(51) Int. Cl. H05K 7/14

(52) U.S. Cl. CPC H05K 7/1492; H05K 7/14322

(57) ABSTRACT

An adapter set, system and apparatus. The adapter set comprising a first adapter subset configured to be installed in a first bay of a power supply unit (PSU) cage of an information processing device, the first bay being configured to receive a wider form factor PSU, the first adapter subset comprising a first adapter comprising a first adapter attachment feature and a first PSU engagement feature and a second adapter comprising a second attachment feature, a second PSU engagement feature and a PSU connector filler.

### INTRODUCTION

Enterprise information processing systems (e.g., servers) generally include removable power supply units (PSUs) to provide power to the components of the system. These PSUs are removably installed in bays defined in a power supply cage, which is part of the chassis of the system. Multiple PSUs are often provided for the system to allow for redundancy and/or to increase the overall power capacity of the system, and thus the PSU cage may have multiple bays, which each receive a PSU. For example, in a configuration with two PSUs, one PSU can provide redundancy in case the other PSU stops working properly, in which case the non-working PSU can be swapped for a replacement PSU without the need to power off the system. Such configuration enables the server, or any other computing system utilizing the PSU, to continue operation without major interruptions.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example adapter set installed in examples PSU cage and system board.

FIG. 2 is a block diagram illustrating the example adapter set of FIG. 1 further engaged with example power supply units.

FIG. 3 is an exploded view of an adapter set for a CRPS PSU.

FIG. 4 is a perspective view of the assembly of FIG. 3 with CRPS connectors and a portion of a system board.

FIG. 5 is a perspective view of a 73.5 mm form factor CRPS cage without an adapter set installed, with the CRPS connectors and partial system board of FIG. 4.

FIG. 6 is a perspective view of the assembly of FIG. 5 with the adapter set of FIG. 3 installed.

FIG. 7. is another perspective view of the assembly of FIG. 6, with CRPS connectors and partial system board omitted.

FIG. 8. is a perspective view of the assembly of FIG. 7 with 60 mm form factor CRPS units installed.

The drawings are included to provide a further understanding of the present disclosure and are incorporated in and constitute a part of this specification. The drawings illustrate one or more examples of the present teachings and together with the description explain certain principles and operations. In some occasions, details that are not necessary for an understanding of an instance of this disclosure or that render other details difficult to perceive may have been omitted.

### DETAILED DESCRIPTION

PSUs may come in a variety of form factors which may have different dimensions, different engagement features to engage with a PSU cage, different electrical connectors, and the like. The PSU cages, and their bays, are generally configured to be compatible with a particular PSU form factor, which may deem the PSU cages incompatible with other PSU form factors.

In some instances, a manufacturer of information processing devices may desire to utilize multiple PSU form factors in various systems to allow for greater user choice. However, this may require the manufacturer to design and produce multiple different versions of PSU cages to accommodate these different PSU form factors. This may further require users of these systems to replace PSU cages of the systems every time a different PSU form factor is to be used, or in some cases to replace the entire chassis of the system if the PSU cage is permanently affixed to the remainder of the chassis. This can be costly to both the manufacturer and user of these systems, both in terms of materials and labor costs.

One example type of PSU that comes in multiple form factors that may be desirable to interchangeably utilize includes a common redundant power supply (CRPS). CRPS is a family of standards which specify various modular power supply form factors that are hot-swappable and with redundancy capability. The CRPS industry standards define various form factors including a CRPS 73.5 mm width form factor and a CRPS 60 mm width form factor. These CRPS 73.5 mm and 60 mm PSUs differ from one another in their physical dimensions, notably their widths, and also in their edge connectors, notably that the edge connector of the CRPS 60 mm is narrower and includes a lesser number of pins than the edge connector of the CRPS 73.5 mm. Due to these differences, the wider CRPS 73.5 mm PSU will not fit within a bay designed to receive a CRPS 60 mm PSU, and the 73.5 mm PSU edge connector cannot mate with a system socket connector designed to receive a CRPS 60 MM PSU. On the other hand, the narrower CRPS 60 mm PSU can fit within a bay designed for a 73.5 mm PSU and it is possible for the PSU connector of the smaller 60 mm CRPS to utilize a system socket connector designed to receive the 73.5 mm form factor if properly positioned therein. A subset of the pins in the larger system socket are compatible (in position and function) to the pins of the smaller 60 mm PSU edge connector, and thus if these pins are properly aligned during mating, then the smaller 60 mm PSU edge connector can work within the larger system socket. However, because the 60 mm PSU and its edge connector are narrower than the bay and the system socket connector, the engagement features of the bay and socket, which would normally guide the PSU and its edge connector into a proper installed position, will not properly engage with the smaller PSU, and therefore there is no guarantee that the edge connector of the 60 mm PSU will be properly positioned when installed. In other words, when the smaller 60 mm PSU is inserted into the larger system socket, there is a risk that the PSU will be misaligned relative to the system socket and the pins of the 60 mm PSU edge connector will engage with incompatible pins in the system socket (e.g., 12V pins in PSU edge connector engaging with ground pins in system socket, or vice versa), causing a malfunction. Furthermore, the narrower 60 mm PSU cannot engage with both sidewalls of the bay, and thus the PSU will not be held securely in the bay and may move laterally, e.g., due to shock or vibration, which can damage its edge connector or cause it to dislodge from the socket. Thus, it is not possible or not advisable for either CRPS form factor to be used within a bay designed for the other CRPS form factor.

The 73.5 mm and 60 mm CRPS form factors are discussed as two examples above to illustrate some of the compatibility issues between different PSU form factors, but it should be understood that same compatibility issues (and/or others) may arise between any two PSU form factors which have different dimensions, different edge connectors, or other differences.

To address these issues, this disclosure provides an adapter set that allows the interchangeable use of two types of PSU form factors within the same common PSU cage, by the attachment, or detachment, of the adapter set to/from the cage without the need to replace or modify the PSU cage. In some instances, the adapter set may be installed by sliding them into specified positions within a bay of the PSU cage and securing them to the PSU cage through fasteners or other attachment features. The adapters, when installed, may change the internal dimensions of the bay, converting the bay to now fit a smaller PSU form factor than the one it was previously designed to fit. Moreover, the adapters may be configured to engage with the smaller PSU during insertion of the PSU and guide the PSU into a correct installation position which will allow for proper mating between the PSU edge connector and the system socket connector. The adapters may also securely hold the smaller PSU installed in the bay, inhibiting lateral movement thereof. Thus, the same PSU cage can accept a larger PSU form factor (without the adapter installed) or the smaller PSU form factor (with the adapters installed). As a result, a system manufacturer can utilize a common PSU cage design for multiple different systems that utilize different PSU form factors, which can reduce development, manufacturing, and logistical costs. Furthermore, the adapters may allow an owner or user of a system to easily modify their system post-manufacture to use a different PSU form factor without needing to obtain a new system chassis or PSU cage.

In some examples, the adapter set further includes a connector filler to prevent misalignment of pins of a PSU edge connector with pins of the system socket. The adapters may include portions which engage with the sides of the PSU as it is inserted into the bay to provide gross alignment of the PSU, and these may help to align the PSU edge connector with the system socket connect. However, in some cases it may be desired to provide even finer alignment control than can be provided by these side-engaging portions of the adapters and/or it may be desired to have a failsafe feature to ensure no misalignment between pins, and the connector filler may be provided in such cases. The connector filler includes an electrically non-conductive material (e.g., plastic) which is sized and shaped to fit within the slot of the system socket connector. The connector filler is mounted to an end of one of the adapters and configured to, when the adapter is installed, sit within a predetermined portion of the system socket connector thereby physically block access to certain predetermined pins of the system connector. In this position, the connector filler can engage with the side of the PSU edge connector during insertion to provide even finer alignment control to guide the PSU edge connector into a properly aligned position within the system socket connector and/or physically block the PSU edge connector from engaging with certain pins. This can even further assist in avoiding some of the risks of misalignment which were discussed above in relation to the a smaller PSU connector (e.g., the connector of the 60 mm form factor CRPS) being connected to a larger system connector (e.g., 73.5 mm form factor system connector).

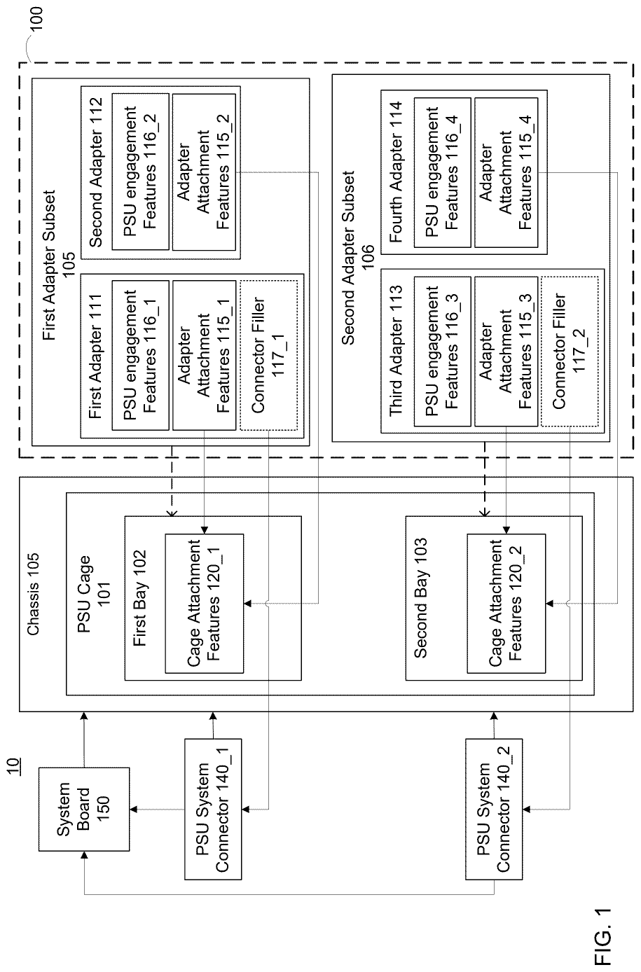

These and other examples will be described in greater detail below in relation to FIGS. 1-8.

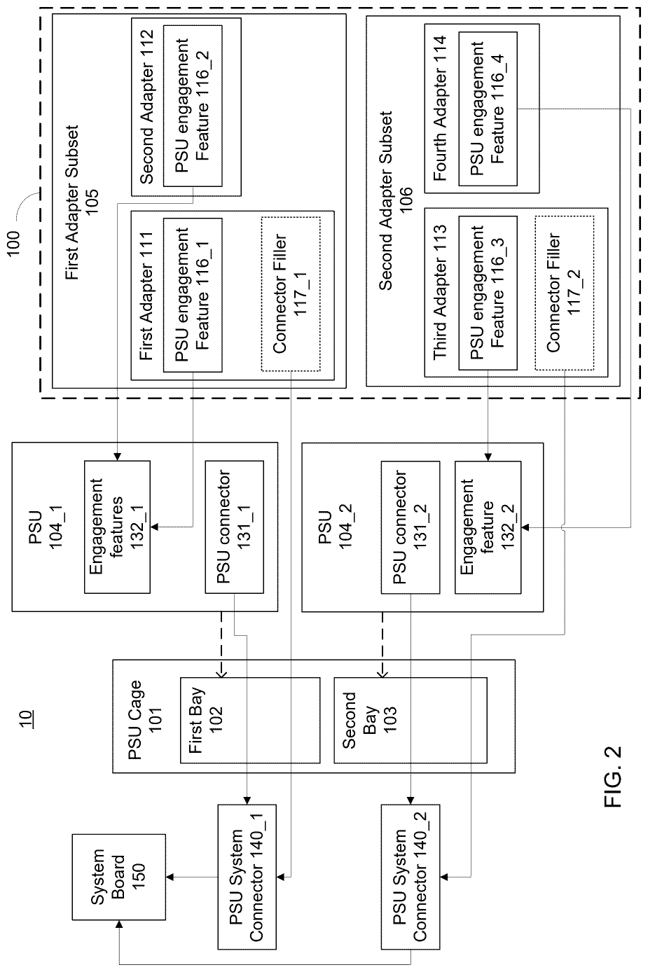

Now referring to FIGS. 1 and 2, an adapter set 100 and a system 10 are presented. The adapter 100 is shown in FIGS. 1 and 2 and described below as a part of the system 10, with the adapter 100 installed in a PSU cage 101 of the system 10, to aid understanding. However, some examples disclosed herein may include the adapter 100 by itself (i.e., in an uninstalled state). FIG. 1 shows the system 10 in a state without PSUs installed, while FIG. 2 shows the system 10 in a state with PSUs 104 installed in PSU cage 101. In FIGS. 1 and 2, solid lines with arrows extending between two boxes represent connections or engagement between the components represented by the boxes, such as physical connection or engagement (contact, coupling, attachment, etc.) and/or electrical connection, as the case may be. Furthermore, dashed lines with arrows extending between boxes indicate that the component represented by the box at the beginning of the arrow is inserted into the component represented by the box at the end of the arrow. It should be noted that some elements may be shown in FIG. 1, but omitted from FIG. 2, and similarly other elements may be omitted from FIG. 1, but shown in FIG. 2, for illustrative purposes only. As such, both FIG. 1 and FIG. 2 may include every element of each other.

In instances, system 10 comprises a chassis 105, a system board 150 supported by the chassis 105, one or more PSU system connectors 140, and a set of adapters 100. The system board 150 may be communicatively (electrically) connected to the PSU connectors 140, which in some examples may include a PSU connector 140_1 and a PSU connector 140_2 as shown in FIGS. 1 and 2. In some examples, PSU connectors 140 may be CRPS connectors.

Referring to FIGS. 1 and 2, system board 150 may be included in an information processing system, such as hypercomputing devices, datacenter servers, networking devices, and the like. A “system board,” as used in this disclosure, is a central circuit board comprising a central processing unit (CPU) and supporting circuitry, and configured to enable connection and integration among a plurality of components and devices. System board 150 may include one or more processors (or socket(s) configured to receive processor(s)), memory (or memory sockets), and/or other devices not described. In instances, system board 150 may include conductive pathways used for electrical and data transfers.

The system board 150 and other components (not illustrated) of the system receive power from one or more PSUs 104, which are installed in a PSU cage 101 (described below). The PSUs 104 may be electrically connected to the system board 150 via PSU system connectors 140, which mate with PSU connectors 131 of the PSUs 104. These PSU system connectors 140 may be supported by the chassis 105, directly (e.g., via direct attachment to the chassis 105) or indirectly (e.g., via attachment to the system board 150 or other board, such as a power distribution board, which is in turn secured to the chassis 105). The PSUs 104 may also be electrically connected to other peripheral components (not illustrated), in some cases via the system board 150 (e.g., via internal conductive pathways in the system board which distribute power and/or data signals) and in other cases via wires/cables which extend directly between the PSU 104 and a peripheral component.

System board 150 may be supported by a chassis 105, which may include a support structure such as an enclosure or tray, designed to support, and in some cases house, hardware components. The chassis 105 includes a PSU cage 101, which may be attached to other portions of the chassis 105 such as a base and/or side walls.

PSU cage 101 includes one or more bays to receive PSUs. In FIGS. 1 and 2, the PSU cage 101 is shown with two such bays as an example, namely a first bay 102 and a second bay 103. However, any number of bays may be included in the PSU cage 101. FIG. 1 shows each of first and second bays 102/103 with respective cage attachment features 120_1 and 120_2. It should be noted that attachment features 120_1 and 120_2 are omitted from FIG. 2 for illustrative purposes, but are still present in the cage 101. The bay(s) of the PSU cage 101 (e.g., bays 102 and 103) are configured to fit a first form factor of PSU (not illustrated) therein. Thus, the space inside the bays in which the PSU is to be received may have dimensions which are similar to the outer dimensions of the PSU so that the PSU can fit in the bay while still being held securely therein. In particular the bays may have engagement features configured to engage with and guide the PSU into a proper installation position within the bay and also to hold and support the PSU once installed. These engagement features may include, for example, two opposing side walls which engage with side walls of the first form factor PSU to control the lateral positioning of the PSU within the bay. Rails, tracks, or other engagement features may also be used, in some examples. A distance between these engagement features may be a first width, which may be similar to (the same as or slightly larger than) the width of the first form factor of PSU.

The PSU system connectors 140 are positioned adjacent to and/or in corresponding bays of the PSU cage 101 at predetermined positions which will allow for blind matting between a PSU connector of the first form factor PSU and the system connector 140 when the PSU is inserted into the bay. For instance, in FIGS. 1 and 2 where two bays 102 and 103 are shown, there are two corresponding PSU system connectors 140_1 and 140_2, with the PSU system connector 140_1 being positioned adjacent or in first bay 102 and PSU system connector 140_2 being positioned adjacent or in second bay 103. In some instances, the PSU system connectors 140 may be attached directly to the PSU cage 101 (e.g. PSU system connector 140_1 is attached to first bay 102 and PSU system connector 140_2 is attached to second cage 103). In some examples, the chassis 105 may include a rear panel and the PSU cage 101 may be disposed at, and form part of, the rear panel such that PSUs 104 are inserted into the bays of the PSU cage 101 through openings in the rear panel.

The adapter set 100 includes at least one subset of adapters, with each subset of adapters being configured to convert a given bay of the PSU cage 101 to accept a second form factor of PSU, such as PSUs 104_1 and 104_2 shown in FIGS. 1 and 2, instead of the first form factor of PSU. The first and second form factors of PSU differ from one another at least in that they have different dimensions (e.g., widths), and may also in some examples have different connectors. In some examples, the first form factor comprises a CRPS 73.5 mm form factor and the second form factor comprises a CRPS 60 mm form factor. In FIGS. 1 and 2, two subsets of adapters are shown, namely a first adapter subset 105 for converting first bay 102 and a second adapter subset for converting second bay 103. In other examples, fewer or more subsets of adapters may be used, depending on the number of bays it is desired to convert.

First adapter subset 105 includes a first adapter 111 and a second adapter 112. In instances, first and second adapters 111/112 engage with first bay 102. The first adapter 111 includes PSU engagement features 116_1 and adapter attachment features 115_1. In instances, first adapter 111 may include a connector filler 117_1. In instances, connector filler 117_1 engages with a portion of PSU system connector 140_1. The second adapter 112 includes a PSU engagement feature 116_2 and adapter attachment features 115_2.

Referring to FIG. 1, the adapter attachment features 115_1 and adapter attachment features 115_2 are configured to, respectively, engage with cage attachment features 120_1 to attach the adapters 111 or 112 to the cage 101. For example, the first adapter subset 105 may be is inserted in the first bay 102 with the first adapter 111 in a first predetermined position (e.g., adjacent one sidewall of the bay 102) and the second adapter 112 in a second predetermined position (e.g., adjacent another sidewall of the bay 102), and then the adapter attachment features 115_1 and 115_2 may be fastened to corresponding cage attachment features 120_1 to secure the adapters 111 and 112 in these predetermined positions. In an example, adapter attachment features 115_1 and 115_2 may include protrusions and the cage attachment features 120_1 comprise recesses configured to mate with the protrusions (or vice versa). In some examples, the adapter attachment features 115_1 and 115_2 and the cage attachment features 120_1 both comprise fastener holes configured to receive a fastener, such as a screw. In some examples, the adapter attachment features 115_1 and 115_2 comprise latches and the cage attachment features 120 comprise complementary latch receivers (or vice versa). In some examples, multiple different types of attachment features 120 may be used in conjunction.

When the first adapter set 111 is fully installed (i.e., positioned in bay 102 and fastened to cage attachment features 120_1), the first and second adapters 111 and 112 define space therebetween which is smaller than the space previously defined by the first bay 102. In other words, the first adapter set 111 reduces the size of the open space within the bay 102. The first adapter set 111 is configured such that this new smaller space will fit the second form factor of PSU. In particular, the first and second adapters 111 and 112 comprise PSU engagement features 116_1 and 116_2 which are configured to engage with the second form factor of PSU, in lieu of the engagement features of the bay 102. The sizes and positions of the first and second adapters 111 and 112 are configured such that the PSU engagement features 116_1 and 116_2 will guide the second form factor PSUs into a proper installed position, as will be discussed below. They also may hold and support the PSUs once installed. These PSU engagement features 116_1 and 116_2 may be spaced apart by a second width which is smaller than the first width and which is similar to a width of the second form factor PSU.

The adapter set 100 may include a second adapter subset 106. The second adapter subset 106 includes a third adapter 113 and a fourth adapter 114. The third adapter 113 includes PSU engagement features 116_3, adapter attachment features 115_3 and a connector filler 117_2. The fourth adapter 114 includes PSU engagement features 116_4 and adapter attachment features 115_4. The adapter attachment features 115 _3/115_4 are configured to engage with the cage attachment features 120_2 of the second bay 103 in a similar manner as described above with respect to the adapter attachment features 115_1/115_2. The PSU engagement features 116_3/116_4 are configured to engage and guide a second form factor PSU installed in the second bay 103 in a similar manner as described above with respect to the PSU engagement features 116_1/116_2. Examples of adapter attachment features 115 _3/115_4, and PSU engagement features 116_3/116_4 may be the same, or include, examples described in reference to, respectively, adapter attachment features 115_1/115_2 and PSU engagement features 116_2.

Referring to FIG. 2, the installation of second form factor PSUs will be described. A first PSU 104_1 of the second form factor may be installed in the first bay 102, and a second PSU 104_2 of the second form factor may be installed in the second bay 103. In this state, adapter 100 is engaged with the PSU 104_1 and a PSU 104 _2. In instances, PSU 104_1 includes engagement features 132_1 and PSU connector 131_1, and PSU 104_2 includes PSU connector 131_2 and engagement features 132_2. In instances, PSU 104_1 is connected to PSU system connector 140_1, and PSU 104_2 is connected to PSU system connector 140_2. In instances, PSU 104_1 and 104_2 have a 60 mm CRPS form factor. PSU 104_1 includes a PSU connector 131_1, while PSU 104_2 includes PSU connector 131_2. In an example, PSU 104_1 connects to PSU system connector 140_1 using PSU connector 131_1. In instances, system 10 includes configurations in which one or both PSUs may be included. In example configuration where both PSU are installed, PSU connector 131_1 and PSU connector 131_2 respectively connect to PSU system connector 141_1 and PSU connector 141_2.

In a configuration where only one PSU is installed, first adapter subset 105 may be used in conjunction with PSU 104_1. For example, in other examples, both first and second adapter subsets 105/106 may be used in conjunction with PSU 104_1 and 104_2. As the PSU 104 is being inserted into first bay 102, the engagement features 132_1 engages with the PSU engagement features 116_1 and PSU engagement features 116_2 such that the PSU engagement features 116_1/116_2 guide PSU 104_1 into an installed position in which the PSU connector 131_1 can mate with the PSU system connector 140_1. The engagement features 132_1 and PSU engagement features 116_1 and 116_2 may comprise any complementary engagement features, such as opposing flat surfaces that contact and slide against one another, rails or tracks and tabs/rollers to slide or roll along the rails/tracks, etc. In some examples, PSU engagement features 116_1/116_2 may be flat surfaces used for ensuring PSU connector 131_1 is aligned with PSU system connector 141_1. Similarly, PSU engagement features 116_3 and 116-4 are configured to engage with engagement features 132_2 as to guide PSU 104_2 into its proper installation position within second bay 103 and ensuring alignment between PSU connector 131_2 and PSU system connector 140_2.

As noted above, the second form factor of a PSU installed with adapter set 100 will be a narrower than the first form factor of PSUs normally used with the PSU cage 101. Furthermore, the PSU connectors 131_1/131_2 of the second form factor PSUs may be narrower than and have fewer pins than the PSU connectors of the first form factor PSUs, and because the PSU system connector 141_1/140_2 of the system board 150 are designed to receive the PSU connectors for the first form factor PSUs, the PSU connectors 131_1/131_2 may also be narrower than and have fewer pins that the system connector 141_1/140_2. However, the PSU connectors 131_1 and 131_2 may still be useable with the PSU system connectors 140_1 and 140_2, in some examples, as long as the PSU connectors 131_1 and 131_2 are properly positioned relative to the system connectors 140_1 and 140_2 so that corresponding pins of both connectors are aligned. For example, to help ensure that the pins of PSU connector 131_1 are properly aligned with the corresponding pins of PSU system connector 140_1, first adapter 11 inserts the connector filler 117_1 into a socket of the PSU system connector 140_1 such that the connector filler 117_1 covers/blocks certain predetermined pins of the PSU system connector 140_1, preventing access to these of pins. Thus, the PSU connector 131_1 cannot inadvertently connect to these blocked pins, which might cause a malfunction. In configurations where a second PSU (i.e. PSU 104_2) is used, connector filler 117_2 may be attached to PSU system connector 140_2 to ensure proper connection between PSU system connector 140_2 and PSU connector 131_2.

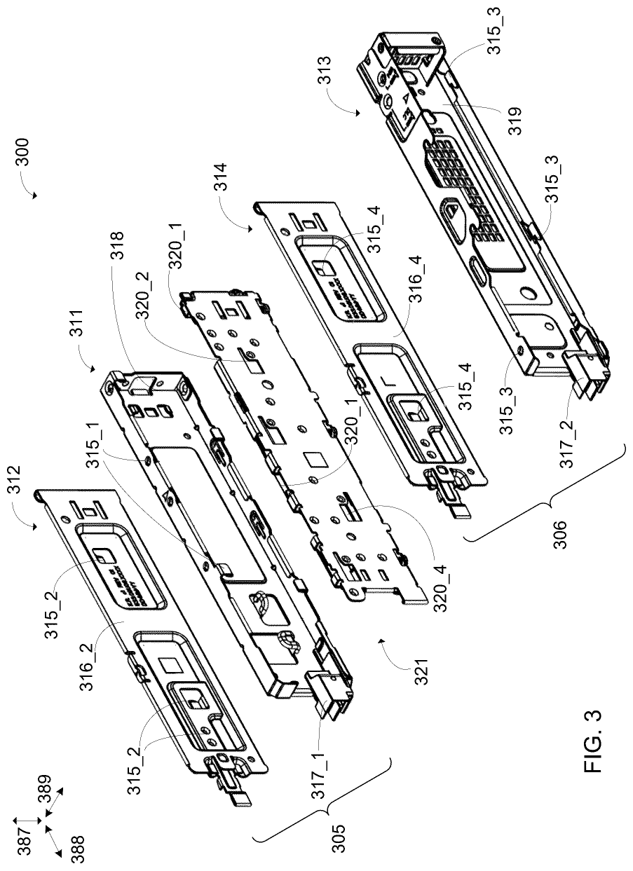

Now referring to FIGS. 3-8, an example adapter set 300 will be described. Adapter set 300 is an example implementation of adapter set 100. A cage divider 321 is also shown in association with the adapter set 300 for ease of description, but the cage divider is not necessarily included as part of the set 300 in some examples.

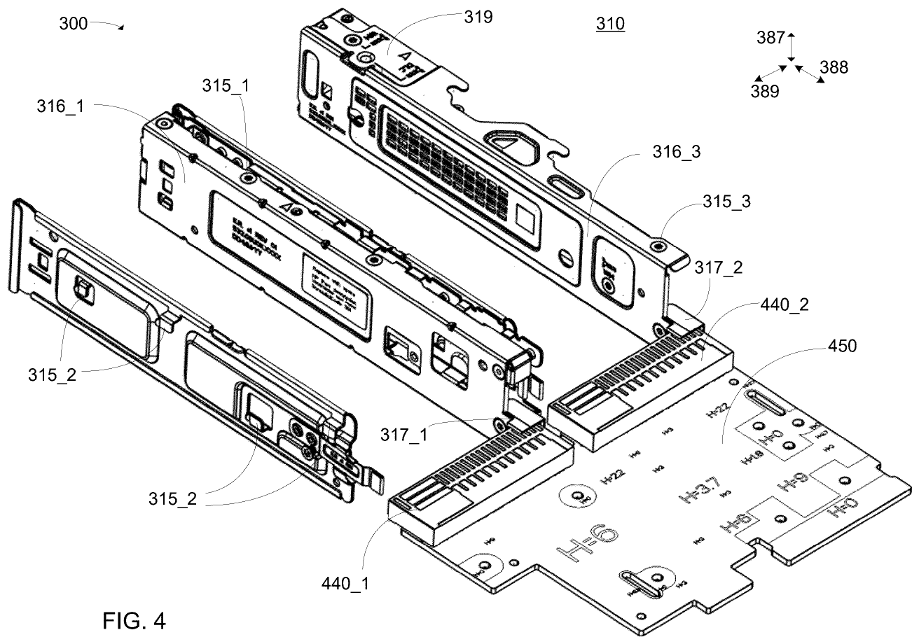

FIGS. 4-8 further illustrate an example information processing system 310, or isolated components thereof, in which the adapter set 300 may be installed. The information processing system 310 is an example implementation for the system 10. Components of the information processing system 310 include example PSU system connectors 440_1/440_2 and an example chassis 305 (including a PSU cage 301), which are example implementations, respectively, of PSU system connectors 140_1/140_2 and chassis 105. System 310 further includes a printed circuit assembly (PCA) 451. In some examples, PCA 451 is a system board, in which case it may be an example implementation of system board 150. In other examples, PCA 451 may be a power distribution board, which is in turn connected to a system board (not illustrated) of the system 310. It should be noted that various components of PCA 451, such as data processing and power management components, are omitted from the figures for ease of illustration.

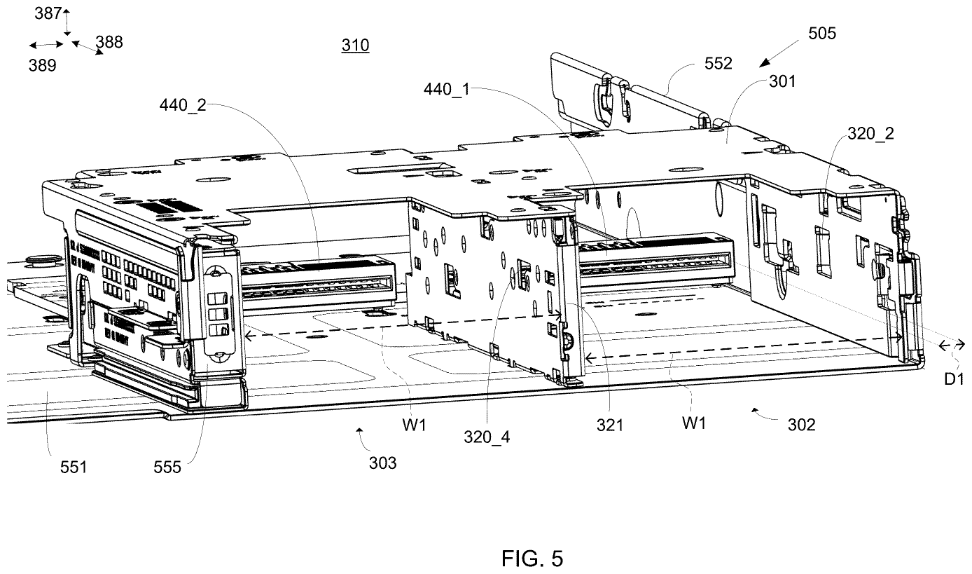

FIG. 5 shows the system 310 in a state in which the PSU cage 301 does not have an adapter set installed. PSU cage 301 is an example implementation of PSU cage 101.

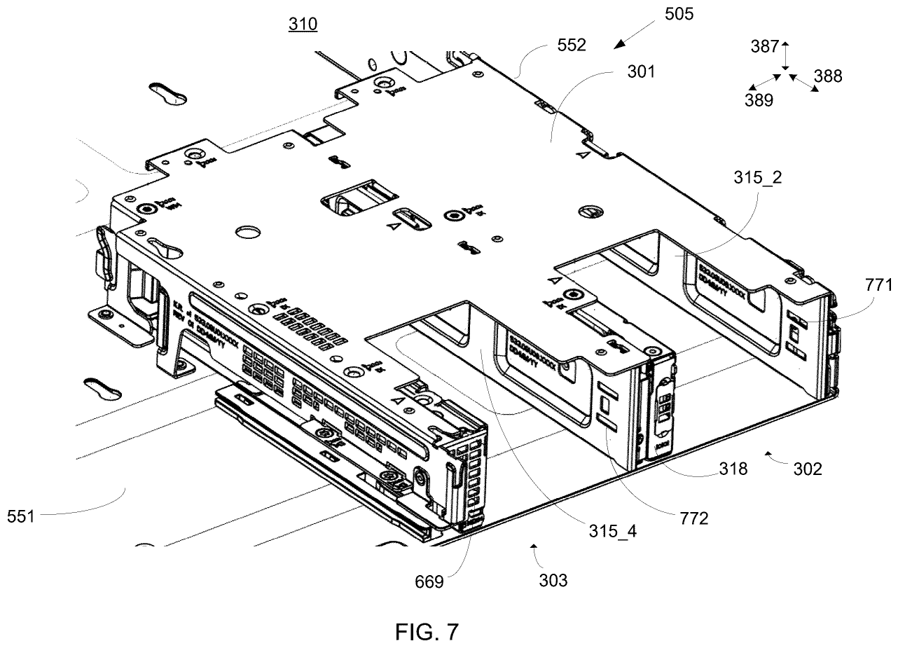

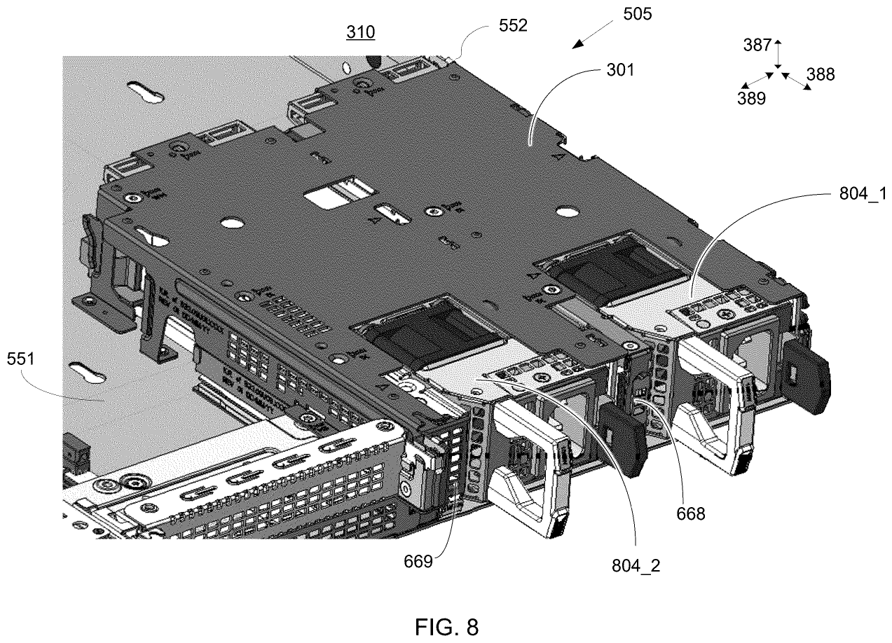

FIG. 7 shows the system 310 in a state in which the example adapter set 300 is installed in the PSU cage 301 without the PSUs installed, while FIG. 8 shows the system 310 in a state in which the adapter set 300 is installed in the PSU cage 301 and two 60 mm form factor CRPS are also installed.

In the examples, adapter set 300, PSU cage 301, PSU system connectors 440_1/440_2, PCA 451, and other components in reference to FIGS. 3-8 are described simultaneously below for ease of understanding. However, it should be noted that the example components may be produced or sold together or separately and may be claimed separately or together herein. Elements in FIGS. 3-8 and elements of FIGS. 1-2 whose reference numbers have the same last two digits as elements described above in relation to FIGS. 1 and 2, such as 100 and 300, correspond to one another, with elements in FIGS. 3-8 being one implementation example of the corresponding element in FIG. 1-2.

Elements in reference to FIGS. 3-8 are described using vertical 387, longitudinal 388 and latitudinal 389 axes for ease of description. Vertical axis 387 is perpendicular to base 551 of the chassis 505, or when referring to a component in isolation (such as adapter set 300 by itself), the vertical axis 387 is an axis which would be perpendicular to the base 551 upon the component being installed in the chassis 505. A vertical direction refers to a direction parallel to the vertical axis 387, and these vertical directions may include up and down. Longitudinal 388 and latitudinal 389 axes are perpendicular to each other and to the vertical direction 387 and parallel to the base 551, or when referring to a component in isolation (such as adapter set 300 by itself), the axes 388 and 389 are axes which would be parallel to the base 551 upon the component being installed in the chassis 505. The axes 388 and 389 and may both also be referred to as being a “horizontal” on occasion. A horizontal direction refers to a direction parallel to one of the longitudinal axis 388 and latitudinal axis 389, and these horizontal directions may include left and right along the lateral axis 389 and forward and rearward along the longitudinal axis 388. However, it should be noted that these directional descriptions are used only relative to the system 310 as shown in the Figures. As such, for example, vertical axis 387 does not necessarily have to be perpendicular relative to the ground, depending on the orientation of the system 310 or.

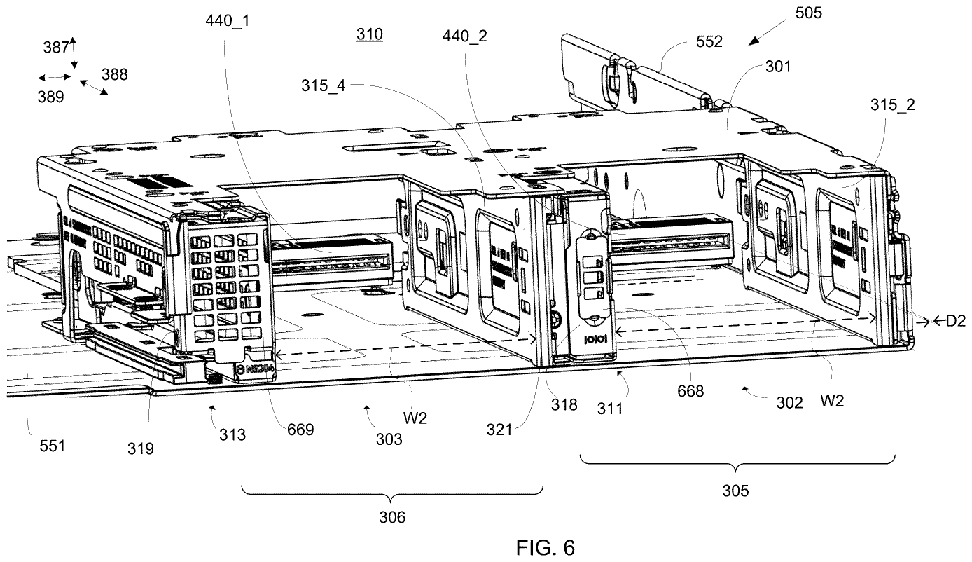

Referring to FIG. 3, adapter set 300 includes a first adapter subset 305 and a second adapter subset 306. The first adapter subset 305 includes a first adapter 311 and a second adapter 312. The first adapter 311 includes adapter attachment features 315_1, connector filler 317_1 and PSU engagement features 316_1, shown in FIG. 4. In this example, adapter attachment features 315_1 include fasteners attaching to the PSU cage 301, shown in FIGS. 6 and 7, and protrusions configured to attach to recesses (i.e. cage attachment features 320_1) of cage divider 321. Referring to FIG. 4, PSU engagement features 316_1 are a flat surface configured to guide a PSU towards a connected position with PSU system connector 440_1. In this example, the engagement features 316_1 are configured to guide a 60 mm form factor CRPS towards the connected position. The connector filler 317_1 attaches to a portion of the PSU system connector 440_1. As shown in FIG. 4, by attaching to a portion the PSU system connector 440_1, connector filler 317_1 ensures that connector pins on a CRPS being installed are aligned and connected to the remaining sockets of the PSU system connector 440_1.

In this example, first adapter 311 also includes a serial port receiver 318. The serial port receiver includes an opening or installing a serial port connector and spacing between the wall of the first adapter facing a CRPS and the cage divider 321, which enables installation of any necessary wiring for a serial port connection. Referring to FIG. 6, in a state where a serial port is not installed, the first adapter includes a port cover 668. The port cover 668 may be a metal piece. In instances, the port cover 668 may include opening for allowing airflow into the first adapter 311.

The second adapter 312 includes adapter attachment features 315_2 and PSU engagement features 316_2. Adapter attachment features 315_2 include fasteners and protrusions configured to attach to cage attachment features 320_2, shown in FIG. 5, the PSU cage 301. Similarly to described above, PSU engagement features 316_2 are flat surfaces configured to guide, in conjunction with PSU engagement features 316_1, the 60 mm CPRS towards a connected position with PSU system connector 440_1, shown in FIG. 4.

The second adapter subset 306 includes a third adapter 313 and a fourth adapter 314. Third adapter 313 includes adapter attachment features 315_3, PSU engagement features 316_3, shown in FIG. 4, and connector filler 317_2. Similar to described above, adapter attachment features 315_3 include fasteners, for attaching to a top side of PSU cage 301, and protrusions, for attaching to recesses on side wall of PSU cage 301. The PSU engagement features 316_3, similar to previous descriptions, are flat surfaces for guiding a CRPS towards PSU system connector 440_2. Similar to first adapter 311, connector filler 317_2 is used for blocking the non-usable sockets in the PSU system connector 440_2, preventing accidental misalignment of the pins of the CRPS with the usable sockets of the PSU system 440_2. It should be noted that usable and non-usable refers to the connection with a 60 mm form factor CRPS. In instances, third adapter 313 includes a boot device module receiver 319. The boot device module receiver 319 is an opening between a wall of PSU cage 301 and the surface of adapter 313 facing a CRPS unit, configured to receive a boot device module. In instances, the device boot module may include M.2 solid state drives (SSD). As shown in FIG. 6, in a state where no device boot module is installed, boot device module receiver 319 includes a module cover 669. In instances, the module cover 669 may include plastic or metal covers. In instances, the module cover may include a grill structure that allows for air flow through the cover.

In instances, the fourth adapter includes adapter attachment features 315_4 and PSU engagement features 316_4. Adapter attachment features 315_4 include fasteners and protrusions configured to attach to cage attachment features 320_4 of the cage divider 321 of the PSU cage 301. Similar to above described, PSU engagement features 316_4 are flat surfaces configured to guide, in conjunction with PSU engagement features 316_3, the 60 mm CPRS towards a connected position with PSU system connector 440_2.

Now referring to FIG. 5, PSU cage 301 is shown without the adapter set 300. In this example, the PSU cage 301 is attached to a base 551 of system chassis 505, as well as being attached to (or forming a part of) a sidewall 552 of the system chassis 505. In this example, the cage includes a serial port enclosure 555.

Continuing on FIG. 5, with PSU cage 301 without the adapter set 300 installed, bays 302 and 303 each have an internal width of W1 between a side of cage divider 321 and a side wall of the PSU cage 301. The width W1 corresponds to the same as, or slightly wider width than, the width of the first form factor PSU. For example, the width W1 may correspond to a width of a 73.5 mm form factor PSU. In an example, the width W1 may be slightly wider than the width of a 73.5 mm form factor PSU, such as [example width].

In FIG. 6, the PSU cage 301 is shown with the adapter set 300 installed. In instances, installing the adapter set 300 in the PSU cage 301, may include removing the serial port adapter 555. Installing the adapter set 300 may further include attaching adapter attachment features 315_1-315_4 to PSU cage 301, including cage divider 321. In instances, PSU cage 301 may include a ridge protruding from the top side of the PSU cage 301, configured to prevent a narrower PSU, such as a 60 mm CRPS, from being installed without the adapter set 300. In this situation, installing the adapter set 300 includes removing the ridge.

Continuing on FIG. 6, with PSU cage 301 with the adapter set 300 installed, the width between the first and second adapters 311/312 and between third and fourth adapters 313/314 are reduced to width W2. The width W2 is a reduced width corresponding to the same as, or slightly wider than, the width of the second form factor PSU. In an example, the width W2 may be the same as the width of a 60 mm form factor PSU. In another example, the width W2 may be slightly wider than the width of a 60 mm form factor PSU, such as [example width].

As described above, the adapters 305 and 306 reduce the width of bays 302 and 303, respectively, to the width W2, as shown in FIG. 6. The reduction in width is accomplished by occupying a space within the bays 302 and 303 that is sufficient to reduce the width of the bays to a space that is sufficiently narrow to accommodate a smaller form factor PSU. As described above, adapters subsets 311 and 313 occupy a larger area as these adapter subsets 311/313 enable the attachment of a serial port receiver 318 and a boot device module receiver 319, respectively. Furthermore, as is shown in FIGS. 3 and 4, the adapter subsets 311/313 include the connector fillers 317_1/317_2 and the connector fillers 317_1/317_2 occupies a portion of the width of the adapter subsets 311/313. Thus, a person of ordinary skill in the art will appreciate that the adapter subsets 311/323 are wider than adapter subsets 312/314 as to provide sufficient reduction of the width and to occupy the space of the unused pins of socket of PSU connector 313_/313_2. Which are filled by the connector fillers 317_1/317_2.

Further, as shown in FIG. 5, there is a distance D1 between a side wall of the PSU cage 301 and the PSU connector 440_1. This distance D1 is due to the form factor of the wider PSU, which in this example is a 73.5 mm PSU. In FIG. 6, the adapter subsets 312/314 occupies a space within bays 302/303 that reduces the space between the wall of the adapter subsets 312/314 and the PSU system connectors 404_1/4040_2 to a distance D2. This reduction to distance D2 is also due to the form factor of the narrower PSU, in this example the 60 mm form factor PSU, which has a shorter length between the PSU connectors and the side wall of the PSU. It should be noted that the width occupied by adapter subsets 311/313 and 312/314 are designed to provide proper alignment of the narrower PSU with the PSU system connectors 440_1/440_2. Accordingly, a person of ordinary skill in the art would understand that different form factor PSUs have different configurations and positions of the PSU connectors, as such the difference in width of the adapter subsets are designed to accommodate the difference between the PSU form factors.

In an example, referring to FIG. 4, the PSU cage 301, which includes divider 321, is configured to receive a couple of 73.5 mm for factor CRPS. The walls of the cage are flat and configured to guide the 73.5 mm form factor CRPS to PSU system connectors 440_1/440_2. In order to connect 60 mm form factor CRPS units, a first step includes removing the serial port enclosure 555 from the PSU cage 301. It should be noted that in other examples the PSU cage 301 may not include the serial port enclosure, in which case this step would be omitted.

Continuing on the example, with the serial port enclosure 555 not present, the next step includes attaching either the first adapter subset 305 or the second adapter subset 306. Although often systems will use two of the same form factor PSUs for redundancy, only one adapter subset can be installed, supporting only one PSU, if no redundancy is desired.

Continuing with this example by beginning installation of the adapter set 300 with the first adapter subset 305. Installing the adapter subset 305 includes sliding the first adapter 311, referring to FIG. 6, in the longitudinal direction 388 until the connector filler 317_1 is completely attached to an end portion of PSU system connector 440_1 closest to the cage divider 321. Alternatively, or additionally, securing alignment may be based on aligning adapter attachment features 315_1 to cage attachment features (not shown) of the divider on the side of the first bay 402.

Installing the adapter subset 305 also includes sliding the second adapter 312, referring to FIG. 6, in the longitudinal direction 388 until each end of the first adapter 311 is aligned with the ends of the cage divider 321 or/and based on aligning adapter attachment features 315_2 to cage attachment features 320_2 (shown in FIG. 5). Installing the adapter subset 306 would follow similar steps as with adapter subset 305, but in relation to second bay 303.

Referring to FIG. 7, second adapter 312 and fourth adapter 314 include locking recesses 771 and 772, respectively. The locking recesses are recesses configured to receive a locking feature of a PSU. For example, the locking feature may be protrusion attached to a spring that are configured to engage with the locking recesses 7741 or 772, where the protrusion may only disengage by a force being applied, such as a lover or an automate mechanism.

Referring to FIGS. 7 and 8, installing a PSU into a PSU cage with adapter set installed includes inserting each of a 60 mm CRPS 804_1/804_2, as shown in FIG. 8, into the adapter set 300 and PSU cage 301 in the longitudinal direction 388 until the CRPS 804_1/804_2 are fully installed within the PSU cage 301. For example, the CRPS 804_1/804_2 may be fully installed once the locking recesses 771/772 are engaged by a locking feature of the CPRS 804_1/804_2. In another example, the CRPS 804_1/804_2 may be fully installed once connected to PSU system connectors 440_1/440_2.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An adapter set comprising:
a first adapter subset configured to be installed in a first bay of a power supply unit (PSU) cage of an information processing device, the first bay being configured to receive a wider form factor PSU, the first adapter subset comprising:
a first adapter comprising a first adapter attachment feature and a first PSU engagement feature; and
a second adapter comprising a second attachment feature, a second PSU engagement feature and a PSU connector filler,
wherein on condition of the first adapter subset being installed in the first bay:
the first and second attachment features are configured to attach to the PSU cage,
the first and second adapters are configured to convert the first bay to receive a narrower form factor PSU instead of the wider form factor PSU,
the first and second PSU engagement features are configured to engage with the narrower PSU to guide the narrower PSU into mating with a PSU connector of the information processing system, and
the PSU connector filler is configured to mate with a portion of the PSU connector.

2. The adapter set of claim 1, further comprising a second adapter subset configured to be installed in a second bay of the PSU cage, the second bay configured to receive a second wider form factor PSU, the second adapter subset comprising:
a third adapter comprising a third adapter attachment feature and a third PSU engagement feature; and
a fourth adapter comprising a fourth attachment feature, a fourth PSU engagement feature and a second PSU connector filler, wherein on condition of the second adapter subset being installed in the second bay:
the third and fourth attachment features are configured to attach to the PSU cage,
the third and fourth adapters are configured to convert the second bay to receive a second narrower form factor PSU instead of the wider PSU,
the first and second PSU engagement features are configured to engage with the second narrower PSU to guide the second narrower PSU into mating with a second PSU connector of the information processing system, and
the second PSU connector filler is configured to mate with a portion of the second PSU connector.

3. The adapter set of claim 2, wherein the adapter set comprises a serial port filler.

4. The adapter of claim 2, wherein the adapter set comprises a boot device module filler.

5. The adapter of claim 2, wherein the adapter set is configured to engage with one or more common redundant power supplies (CRPS).

6. The adapter of claim 5, wherein the wider form factor PSU is a 73.5 mm form factor CRPS.

7. The adapter of claim 5, wherein the narrower form factor PSU is a 60 mm form factor CRPS.

8. A computing system, comprising:
a chassis comprising a base and a back panel;
a system board supported by the base, the system board comprising a first power supply unit (PSU) connector;
a PSU cage disposed at or forming part of the back panel comprising a first bay; and
a first adapter subset configured to be installed in the first bay, wherein the first adapter subset comprises:
a first adapter comprising a first attachment feature and a first PSU engagement feature; and
a second adapter comprising a second attachment feature, a second PSU engagement feature and a PSU connector filler, wherein:
in a first configuration, the first bay is configured to receive a wider form factor PSU configured to connect to the first PSU connector, and
in a second configuration, the bay, with the first and second adapters installed, is configured to receive a narrower form factor PSU configured to connect to the first PSU connector, wherein:
the first and second attachment features are configured to attach to the PSU cage,
the first and second PSU engagement features are configured to engage with engagement features of the narrower PSU to guide the narrower PSU into mating with the PSU connector, and
the PSU connector filler is configured to mate with a portion of the first PSU connector.

9. The system of claim 8, further comprising a second adapter subset configured to
be installed in the second bay, wherein the second adapter subset comprises:
a third adapter comprising a third attachment feature and a third PSU engagement feature; and
a fourth adapter comprising a fourth attachment feature, a fourth PSU engagement feature and a second PSU connector filler, wherein:
the PSU cage comprises a second bay,
in a third configuration, the second bay is configured to receive a second wider form factor PSU configured to connect to the second PSU connector, and
in a fourth configuration, the second bay, with the third and fourth adapters installed, is configured to receive a second narrower form factor PSU configured
to connect to the second PSU connector, wherein:
the third and fourth attachment features are configured to attach to the PSU cage,
the third and fourth PSU engagement features are configured to engage with engagement features of the second narrower PSU to guide the second narrower PSU into mating with the second PSU connector, and
the second PSU connector filler is configured to mate with a portion of the second PSU connector.

10. The system of claim 9, wherein the first and second adapter subsets comprise a serial port receiver with a serial port installed in the serial port receiver.

11. The system of claim 9, wherein the second adapter subset comprises a boot device module receiver and a boot device module installed in the boot device module receiver.

12. The system of claim 9, wherein the first and second adapter subsets are configured to engage with one or more common redundant power supplies (CRPS).

13. The system of claim 12, wherein the wider form factor PSU is a 73.5 mm form factor CRPS.

14. The system of claim 12, wherein the narrower form factor PSU is a 60 mm form factor CRPS.

15. An apparatus, comprising:
a first PSU connector of an information processing system;
a PSU connected to the first PSU connector;
a PSU cage attached to the information processing system, wherein the PSU cage comprises a first bay configured to receive a wider form factor PSU; and
a first adapter subset, installed in the first bay, comprising a first adapter and a second adapter, wherein:
the first adapter comprises a first attachment feature and a first PSU engagement feature, and
the second adapter comprises a second attachment feature, a second PSU engagement feature and a PSU connector filler,
wherein:
the first and second attachment features are attached to the PSU cage,
the first and second adapters convert the first bay to receive a narrower form factor PSU instead of the wider form factor PSU;
the first and second PSU engagement features are engaged to engagement features of the narrower form factor PSU, and
the PSU connector filler is mated with a portion of the PSU connector.

16. The apparatus of claim 15, further comprising:
a second PSU connector of the information processing system;
a second bay of the PSU cage; and
a second adapter, installed in the second bay, comprising a third adapter and a fourth adapter, wherein:
the PSU cage comprises a second bay,
the third adapter comprises a third attachment feature and a third PSU engagement feature, and
the fourth adapter comprises a fourth attachment feature, a fourth PSU engagement feature and a second PSU connector filler,
wherein:
the third and fourth attachment features are attached to the PSU cage,
the third and fourth PSU engagement features are engaged to engagement features of the first from PSU, and
the PSU connector filler is mated with a portion of the PSU connector.

17. The apparatus of claim 16, wherein the first and second adapter subsets are configured to engage with one or more common redundant power supplies (CRPS).

18. The apparatus of claim 17, wherein the wider form factor PSU is a 73.5 mm form factor CRPS and the narrower form factor PSU is a 60 mm form factor CRPS.

19. The apparatus of claim 16, wherein the first and second adapter subsets comprise a serial port receiver with a serial port installed in the serial port receiver.

20. The apparatus of claim 16, wherein the second adapter subset comprises a boot device module receiver and a boot device module installed in the boot device module receiver.
